(19) United States
(12) Patent Application Publication
(10) Pub. No.: US 2019/0259722 A1
(43) Pub. Date: Aug. 22, 2019

(54) COPPER PILLARS HAVING IMPROVED INTEGRITY AND METHODS OF MAKING THE SAME

(71) Applicant: Rohm and Haas Electronic Materials LLC, Marlborough, MA (US)

(72) Inventors: Ravi Pokhrel, Framingham, MA (US); Michael K. Gallagher, Hopkinton, MA (US)

(21) Appl. No.: 16/255,124

(22) Filed: Jan. 23, 2019

Related U.S. Application Data
(60) Provisional application No. 62/633,230, filed on Feb. 21, 2018.

(51) Int. Cl. H01L 23/00; C25D 5/02; C25D 7/12; C25D 5/10

(52) U.S. Cl. CPC H01L 24/13; C25D 5/022; C25D 3/38; C25D 5/10; H01L 24/11; C25D 7/12

(57) ABSTRACT

The copper pillars have improved integrity such that they can readily withstand the harsh reflow conditions of post solder bump application without readily failing. The method of making the copper pillars having the improved integrity involves a two-step electroplating process of varying current densities.

### FIELD OF THE INVENTION

The present invention is directed to copper pillars having improved integrity and methods of making the copper pillars. More specifically, the present invention is directed to copper pillars having improved integrity and methods of making the copper pillars such that the copper pillars do not readily fail post solder bump application and reflow.

### BACKGROUND OF THE INVENTION

Copper pillars are photoresist defined features for integrated circuit chips and printed circuit boards. The features are formed by the process of lithography where a photoresist is applied to a substrate such as a semiconductor wafer chip often referred to as a die in packaging technologies, or epoxy/glass printed circuit boards. The photoresist is applied to a surface of the substrate and a mask with a pattern is applied to the photoresist. The substrate with the mask is exposed to radiation such as UV light. The sections of the photoresist which are exposed to the radiation are developed away or removed exposing the surface of the substrate. An outline of a plurality of apertures is formed with the unexposed photoresist left on the substrate forming the walls of the apertures. The surface of the substrate includes a metal seed layer or other conductive metal or metal alloy material which enables the surface of the substrate conductive. The substrate with the patterned photoresist is then immersed in a copper electroplating bath, and copper is electroplated in the apertures to form the pillars. When electroplating is complete, the remainder of the photoresist is stripped from the substrate with a stripping solution and the substrate with the photoresist defined features is further processed.

Copper pillars, are typically capped with solder to enable adhesion as well as electrical conduction between the semiconductor chip to which the pillars are plated and a substrate. Such arrangements are found in advanced packaging technologies. Solder capped copper pillar architectures are a fast growing segment in advanced packaging applications due to improved input/output (I/O) density compared to solder bumping alone. A copper pillar with the structure of a non-reflowable copper pillar and a reflowable solder bump has the following advantages: (1) copper has low electrical resistance and high current density capability; (2) thermal conductivity of copper provides more than three times the thermal conductivity of solder bumps; (3) can improve traditional BGA CTE (ball grid array coefficient of thermal expansion) mismatch problems which can cause reliability problems; and (4) copper pillars do not collapse during reflow allowing for very fine pitch without compromising stand-off height.

Of all the copper pillar bump fabrication processes, electroplating is by far the most commercially viable process. In the actual industrial production, considering the cost and process conditions, electroplating offers mass productivity and there is no polishing or corrosion process to change the surface morphology of copper pillars after the formation of the copper pillars. The ideal copper electroplating chemistry and method for electroplating copper pillars yields deposits with good uniformity, preferably, flat or dished tops and void-free intermetallic interfaces after reflow with solder. Flat or dished pillar tops are generally preferred in the industry as solder bumps applied to domed top pillars tend to flow off the top and down along the sides of the pillars during reflow. In addition, it is highly preferred in the industry to plate at high deposition rates to enable high wafer through-out. High deposition rates typically exceed current densities of 10 ASD, more typically, greater than 15 ASD and even more typically 20 ASD or greater.

During formation of copper pillars by electroplating and electroplating tin or tin alloy solder bumps on the copper pillars, the copper pillars and solder bumps become exposed to a number of various stresses which can lead to failure of the copper pillars, in particular, at the copper-tin intermetallic interface where the copper pillar joins to the tin or tin alloy solder bump. Voids, often referred to as Kirkendall voids, form within the copper-tin intermetallic interface. While these voids can be very small in diameter, if a large number of them form within the intermetallic interface, they can coalesce into larger porosities resulting in cracking and lead to solder bump electrical resistance compromising the electrical performance of the copper pillars and solder bumps.

An example of a conventional process for plating copper pillars is illustrated in FIGS. 1A-D where a semiconductor substrate 10, such as a silicon wafer, with a seed layer (not shown), such as a copper seed layer, is provided. The semiconductor substrate is coated with a layer of photoresist 12, such as a positive acting photoresist, and a mask having a pattern of apertures (not shown) is applied over the layer of the photoresist. UV light is applied to the photoresist (not shown). Portions of the photoresist which are exposed to the UV light through the pattern of apertures become soluble to developing solutions and are removed, thus forming a series of apertures 14 and 16 through the photoresist exposing the seed layer on the semiconductor substrate. The substrate with the patterned photoresist is then immersed in a copper electroplating bath where a plurality of domed copper pillars 18 and 20 are plated in the apertures 14 and 16. Current density during copper electroplating typically exceeds 10 ASD, more typically, current density is about 20 ASD. The electroplating is conformal or same plating speed everywhere deposition, not super-conformal or superfilling. Tin or tin alloy solder bumps 22 and 24 are then deposited on the tops of each domed pillar, such as by electroplating, physical or chemical vapor deposition. Typically, the solder bumps are electroplated on the tops of the copper pillars 18 and 20. As shown in FIG. 1C, due to the copper pillars having a domed or convex morphology, the solder bumps tend to plate not just at the tops of the pillars but also irregularly 15 and 17 and undesirably along the sides of the pillars. Following deposition of the solder bumps, the photoresist 12 is removed from the semiconductor substrate with a stripping solvent leaving the copper pillars 18 and 20 with the solder bumps 22 and 24 on the semiconductor substrate 10. The semiconductor substrate with the copper pillars and solder bumps are then reflowed in a reflow oven. After reflow, a copper-tin interface 25 with a substantial number of voids 26 is formed between the solder bumps and copper pillars. As discussed above, such voids can result in cracking of the copper pillar and solder bump structures at the interfaces 25, thus resulting in defective and compromised electrical devices.

Development of plating chemistries and methods to reduce the number of voids at the interface of solder bumps and the copper pillars to reduce the probability of cracking is very challenging for the industry. Copper pillar based structures have already been employed by various manufacturers for use in consumer products such as smart phones and PCs. As Wafer Level Processing (WLP) continues to evolve and adopt the use of copper pillar technology, there will be increasing demand for reliable copper pillar structures.

Accordingly, there is a need for copper pillars having improved structural integrity and methods of making them.

### SUMMARY OF THE INVENTION

The present invention is directed to copper pillars comprising a horizontal base, a vertical section comprising a bottom side and a top side opposite to the bottom side, wherein the bottom side of the vertical section is joined to the horizontal base; a tin or tin alloy solder bump is joined to the top side of the vertical section by a copper-tin intermetallic interface, wherein along a length of the copper-tin intermetallic interface and from copper of the copper pillar to within the copper-tin intermetallic of 5 μm there is a % V=20% or less.

The present invention also includes a method of electroplating copper pillars comprising:
a) providing a substrate comprising a layer of photoresist, wherein the layer of photoresist comprises a plurality of apertures;
b) providing a first copper electroplating bath comprising one or more sources of copper ions, one or more acids, one or more sources of chloride, one or more levelers, one or more accelerators; and one or more suppressors;
c) immersing the substrate comprising the layer of photoresist with the plurality of apertures in the first copper electroplating bath;
d) electroplating a first section of a copper pillar in each of the plurality of apertures at a first current density followed by electroplating a second section of the copper pillar in each of the plurality of apertures at a lower current density than the first current density with the first copper electroplating bath or, in the alternative, electroplating the second section of the copper pillar in each of the plurality of apertures at the lower current density with a second copper electroplating bath consisting of water, one or more sources of copper ions, one or more acids, and, optionally, one or more sources of chloride, one or more levelers, one or more accelerators and one more suppressors;
e) depositing a tin or tin alloy solder bump on a top of the second section of each copper pillar;
f) stripping the photoresist from the substrate leaving an array of copper pillars with tin or tin alloy solder bumps on the top of the second section of each copper pillar; and
g) reflow the array.

The copper pillars of the present invention have improved integrity over many conventional copper pillars. Voids within the copper-tin intermetallic interface joining the copper of the copper pillars with the tin or tin alloy solder bumps are substantially reduced in number post reflow such that failure or cracking at the copper-tin intermetallic interface is significantly reduced or prevented. The reduction in the number of the voids within the copper-tin intermetallic interface reduces the potential for adjacent voids to coalesce to form bigger voids, thus preventing cracking at the interface and separation of the solder bumps from the copper pillars.

### BRIEF DESCRIPTION OF THE DRAWINGS

FIGS. 1A-D are illustrations of a conventional process for plating domed copper pillars where the copper pillars include solder bumps and a copper-tin intermetallic interface having considerable voiding;

FIGS. 2A-C are illustrations of copper pillars of the present invention having a flat, top, dished top and domed top with a solder bump on the top section of each copper pillar and copper-tin intermetallic interfaces substantially free of voids;

FIG. 3 is an illustration of a copper-tin intermetallic interface adjacent a top of a flat top copper pillar of the present invention, wherein the intermetallic interface along its length is substantially free of voids;

FIG. 4 is an illustration of a copper-tin intermetallic interface adjacent a top of a flat top conventional copper pillar, wherein the intermetallic interface along its length contains substantial numbers of voids with varying lengths (diameters);

FIGS. 5A-D is an illustration of a method of making an array of copper pillars of the present invention, wherein the copper pillars have a flat top and copper-tin intermetallic interfaces substantially free of voids along their length;

FIGS. 6A-B is an illustration of an array of dished copper pillars with solder bumps before reflow and then after reflow, wherein the reflowed copper pillars include copper-tin intermetallic interfaces substantially free of voids along their length;

FIGS. 7A-C are SEMs at 3500× of cross sections of copper pillars having dished tops and the copper-tin intermetallic interfaces of the present invention, wherein the intermetallic interfaces include very few voids with very small diameters or the intermetallic interface is substantially free of voids; and

FIG. 8 is a SEM at 3500× of a cross section of a comparative copper pillar having a dished top and a copper-tin intermetallic interface having substantial voids of varying length within the interface and along the length of the interface.

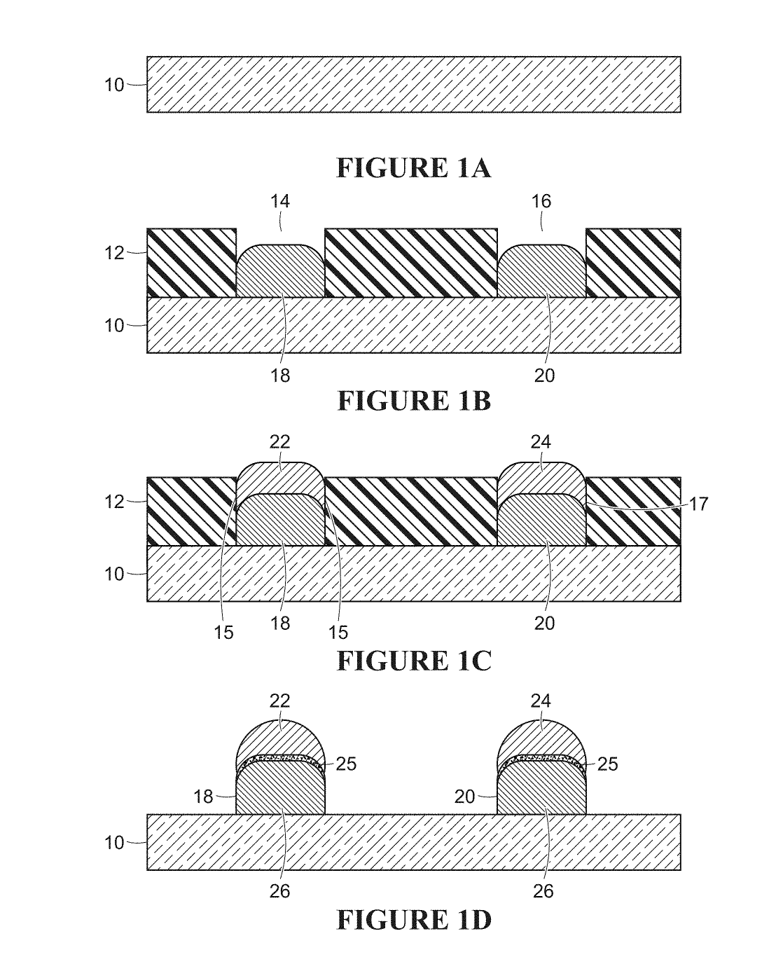

### DETAILED DESCRIPTION OF THE INVENTION

As used throughout this specification the following abbreviations shall have the following meanings unless the context clearly indicates otherwise: A=amperes; A/dm²=amperes per square decimeter=ASD; ° C.=degrees Centigrade; UV=ultraviolet radiation; g=gram; ppm=parts per million=mg/L; L=liter, μm=micron=micrometer; mm=millimeters; cm=centimeters; DI=deionized; mL=milliliter; mol=moles; mmol=millimoles; sec=seconds; C=cycles; Mw=weight average molecular weight; Mn=number average molecular weight; SEM=scanning electron microscope; FIB=focus ion beam; TIR=total indicated runout=total indicator reading=full indicator movement=FIM; Avg.=average; % V=percent voiding; EO=ethylene oxide; PO=propylene oxide; IMC=intermetallic compounds; Cu—Cu₃Sn IMC=copper-tin intermetallic compounds; and NIH=National Institute of Health.

As used throughout this specification, the term “plating” refers to metal electroplating. “Deposition” and “plating” are used interchangeably throughout this specification. “Accelerator” refers to an organic additive that increases the plating rate of the electroplating bath. “Suppressor” refers to an organic additive that suppresses the plating rate of a metal during electroplating. The term “array” means an ordered arrangement. The term “aperture” means opening or hole. The term “domed”=convex. The term “dished”=concave. The term “morphology” means the form, shape and structure of an article. The term “total indicator runout” or “total indicator reading” is the difference between the maximum and minimum measurements, that is, readings of an indicator, on planar, cylindrical, or contoured surface of a part, showing its amount of deviation from flatness, roundness (circularity), cylindricity, concentricity with other cylindrical features or similar conditions. The term “profilometry” means the use of a technique in the measurement and profiling of an object or the use of a laser or white light computer-generated projections to perform surface measurements of three dimensional objects. The term “normalizing” means a rescaling to arrive at values relative to a size variable such as a ratio as % TIR. The term “average” is the mean value of a parameter, wherein the “mean” is the sum of all the samples of a parameter measured or determined divided by the total number of samples. The term “parameter” means a numerical or other measurable factor forming one of a set that defines a system or sets the conditions of its operation. The articles “a” and “an” refer to the singular and the plural.

All numerical ranges are inclusive and combinable in any order, except where it is clear that such numerical ranges are constrained to add up to 100%.

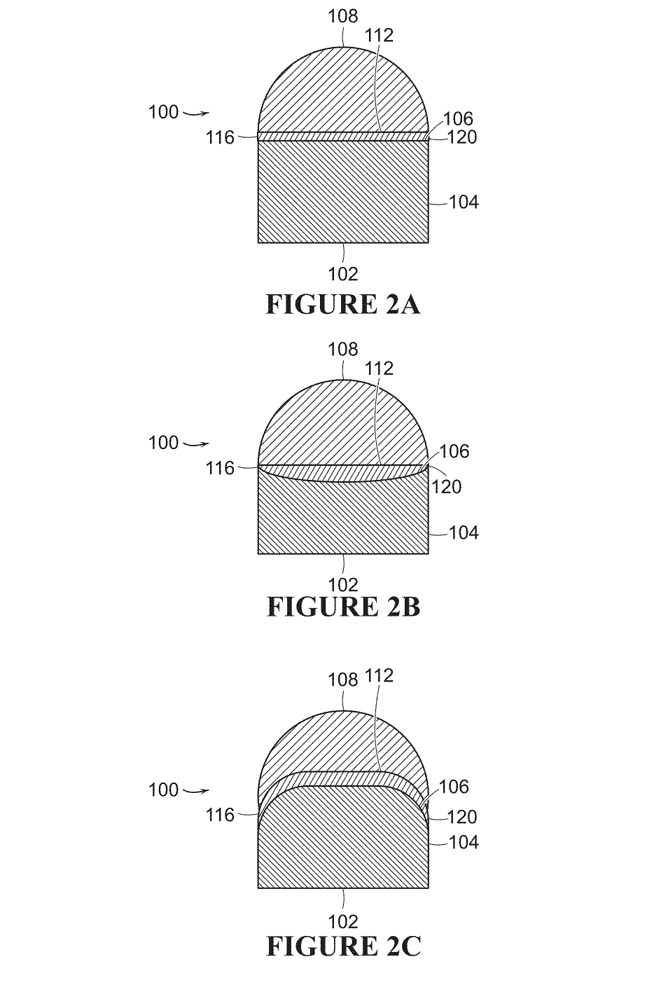

The present invention is directed to a copper pillar 100, wherein the copper pillar comprises a horizontal base 102, a vertical section 104, a top side 106 opposite to the horizontal base. The vertical section 104 is congruous with both top side 106 and the horizontal base 102 to form a single copper pillar structure. The top side can be flat and parallel to the horizontal base as shown in FIG. 2A or the top side can be dished as in FIG. 2B or the top side can be domed as in FIG. 2C.

Preferably, the top side 106 of the copper pillar is flat or dished, more preferably the top side 106 is dished as shown in FIG. 2B. When the top side is flat, the % TIR, preferably, ranges from −1% to +2%, more preferably from 0% to +2%, even more preferably, from 0% to +1%. When the top side is dished, the % TIR, preferably, ranges from −10% to less than −1%, more preferably, from −10% to −7%, even more preferably, from −9% to −7%. When the top of the copper pillar is domed, the % TIR, preferably, ranges from greater than +2% to +10%, more preferably from +2.5% to +10%, even more preferably, from +5% to +10%.

The % TIR of copper pillars can be determined by the following equation:

% TIR=[height_{center}−height_{edge}]/heightₘₐₓ×100

where height_{center} is the height of a pillar as measured along its center axis and height_{edge} is the height of the pillar as measured along its edge at the highest point on the edge. Heightₘₐₓ is the height from the bottom of the pillar to its highest point on its top. Heightₘₐₓ is a normalizing factor.

Individual copper pillar TIRs may be determined by the following equation:

TIR=height_{center}−height_{edge},

where height_{center} and height_{edge} are as defined above.

The parameters of the pillars for determining TIR, and % TIR can be measured using optical profilometry such as with a white light LEICA DCM 3D or similar apparatus.

The copper pillars of the present invention further comprise a tin or tin alloy solder bump 108 and a copper-tin intermetallic interface 116. The copper-tin intermetallic interface joins a bottom section 112 of the solder bump 108 to the top side 106 of the copper pillar to form a complete copper pillar 100 structure.

The copper-tin intermetallic interface 116 has a length 120 from one end of the copper-tin intermetallic interface to the other end and a thickness or width, wherein a majority of voids are concentrated, wherein the thickness ranges, preferably, from 1 μm to 5 μm, more preferably, from 1 μm to 3 μm, even more preferably, from 1 μm to 2 μm, most preferably 1 μm. The widths can be measured using conventional methods well known in the art. The copper pillars of the present invention have a post reflow voiding along the length 120 and width of 20% or less, preferably, from 15% or less, more preferably, from 0.5% to 15%, most preferably, from 0% to 5%.

The post reflow % voiding is determined by the following equation: % V=total length of the number of voids counted along the length (μm) of the interface and within a width of the interface from the copper of the copper pillar to 1-5 μm within the copper-tin intermetallic interface/pillar diameter (μm)×100

The length of the copper-tin intermetallic interface 120 parallels the pillar diameter at the center axis of the pillar and can be equivalent in length to the diameter of the pillar. When the top of the pillar is a dish or domed, the length of the copper-tin intermetallic interface for determining the % V is the length of an ellipse. Conventional equations well known in the art and conventional methods for determining the length of an ellipse can be used.

The number of voids and their lengths (diameters) are counted by conventional counting programs such as software used on images which include, but are not limited to, ImageJ available from NIH in Bethesda, Md., USA (available at https://imagej.nih.gov/ij/). ImageJ from NIH is a public domain, Java-based image processing program developed at the NIH. ImageJ is designed with an open architecture that provides extensibility via Java plugins and recordable macros. Custom acquisition, analysis and processing plugins can be developed using ImageJ's built-in editor and a Java compiler. Voids can range in length (diameter) from less than 0.1 μm to greater than 0.5 μm. The total length of the number of voids within the copper-tin intermetallic interface along the length and width (1-5 μm into the interface) of the copper-tin intermetallic interface is critical since large numbers of small length (diameter) adjacent voids within the interface can coalesce to form much larger voids causing failure of the copper pillars at the copper-tin intermetallic interface.

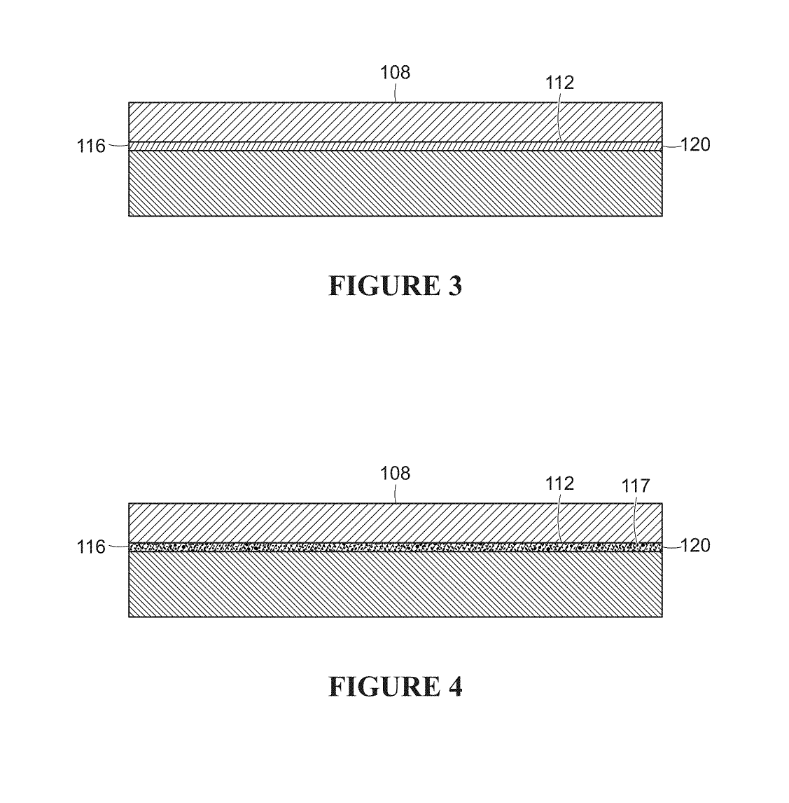

FIG. 3 illustrates a copper-tin intermetallic interface 116 of the present invention which shows the interface along length 120 having a % V substantially=0%, wherein there are no detectable voids. In contrast, FIG. 4 illustrates a conventional copper-tin intermetallic interface outside the scope of the present invention containing substantial amounts of voids 117 of various diameters along the length of the interface 116.

While the present invention is substantially described with respect to methods of electroplating copper pillars having a columnar morphology, the copper pillars can be, for example, oblong, octagonal and rectangular in addition to columnar or cylindrical. The methods of the present invention are, preferably, for electroplating columnar copper pillars. Preferably the columnar copper pillars have a flat top or a dished (concave) top. Preferably, the copper pillars of the present invention have aspect ratios of 3:1 to 1:1 or such as 2:1 to 1:1. A substrate is electroplated by contacting the substrate with the plating bath. The substrate functions as the cathode. The plating bath contains an anode, which may be soluble or insoluble. Potential is applied to the electrodes. Overall average current densities for electroplating the complete copper pillars can range from 0.25 ASD to 40 ASD, preferably 1 ASD to 30 ASD, more preferably from 10 ASD to 30 ASD, most preferably from 10 ASD to 20 ASD.

Copper pillars 200 and 300 of the present invention can be formed by first depositing a conductive seed layer (not shown) on a substrate 202 and 302 such as a semiconductor chip or die to form an array of copper pillars. The substrate is then coated with a photoresist material 204 and 304. The photoresist layer can be applied to a surface of the semiconductor chip by conventional processes known in the art. The thickness of the photoresist layer can vary depending on the height of the pillars. Preferably, the thickness ranges from 40 μm to 250 μm, more preferably, from 40 μm to 50 μm. A patterned mask is applied to a surface of the photoresist layer (not shown) and imaged to selectively expose the photoresist layer to radiation such as UV radiation (not shown). The photoresist layer may be a positive or negative acting photoresist. When the photoresist is positive acting, the portions of the photoresist exposed to the radiation are removed with a developer such as an alkaline developer. A pattern of a plurality of apertures 206 and 306, such as vias, is formed on the surface which reaches all the way down to the seed layer on the substrate. The diameters of the vias can vary depending on the diameter of the pillars. The diameters of the vias can range from 2 μm to 300 μm, preferably, from 50 μm to 225 μm. The entire structure of the substrate and developed photoresist with apertures is then placed in a copper electroplating bath (not shown).

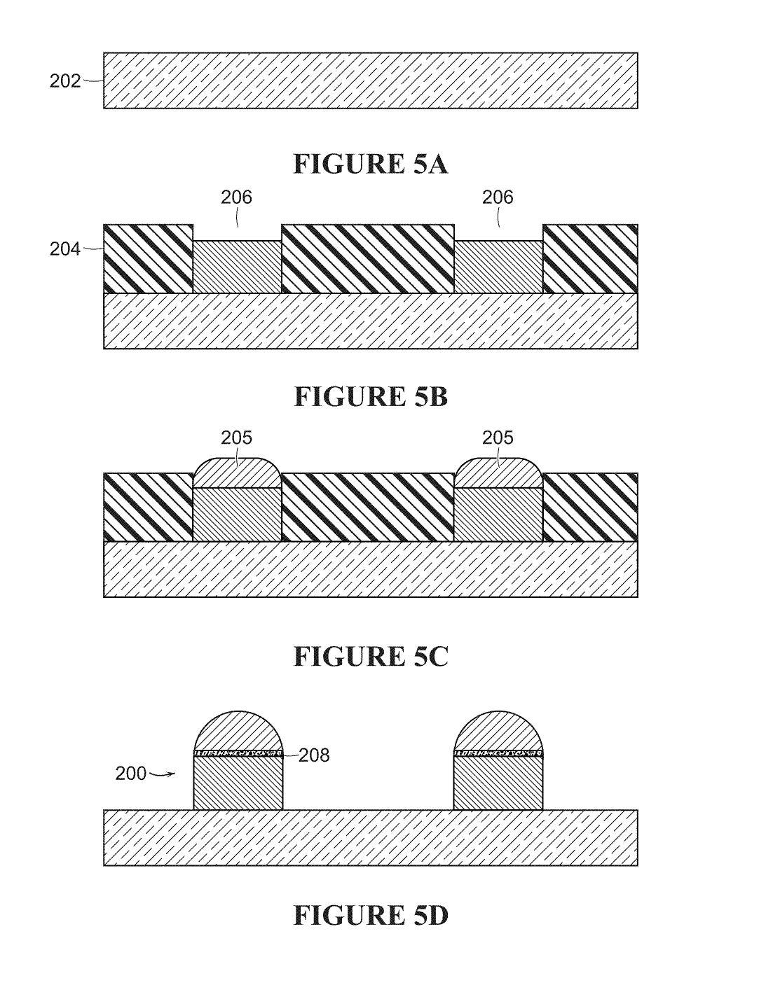

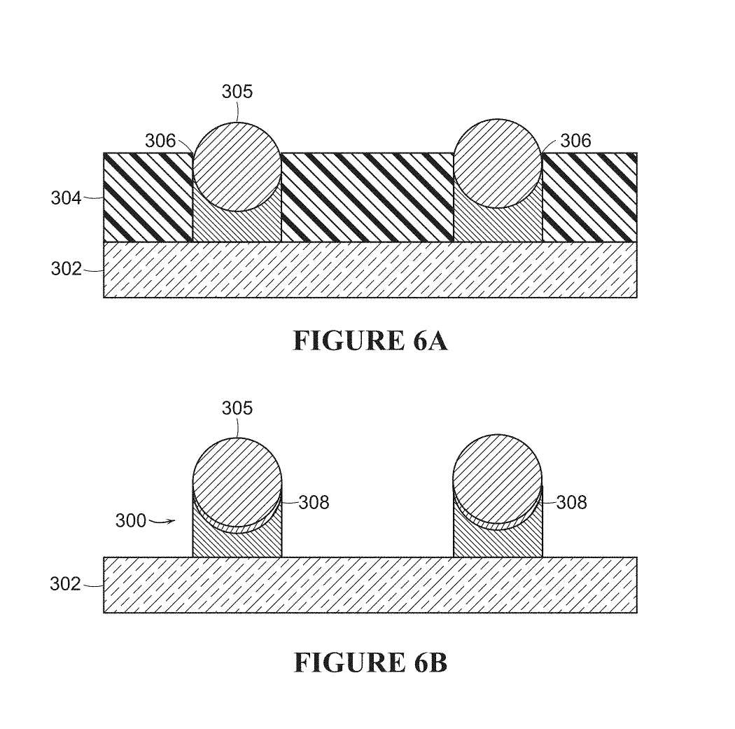

A first section of each copper pillar is electroplated at an initial high current density range. Preferably, the high current density range is greater than 10 ASD, preferably from 15 ASD to 30 ASD, more preferably from 15 ASD to 25 ASD, most preferably from 15 ASD to 20 ASD. High current density is applied for the first 30 μm to 35 μm of height of each copper pillar followed by electroplating the second section or remainder of the copper pillar height at a lower current density than the initial current density. Preferably, the lower current density is 10 ASD or less, preferably, from 0.5 ASD to 10 ASD, more preferably, from 10 ASD to 1 ASD, most preferably, from 8 ASD to 3 ASD. The second section of the copper pillar plated at the lower current densities, preferably, ranges from 1 μm to 10 μm, more preferably, from 1 μm to 5 μm, even more preferably, from 1 μm to 3 μm, most preferably, from 1 μm to 2 μm in height. While FIGS. 5A-D and FIGS. 6A-6B illustrate a method of electroplating flat top copper pillars and dished copper pillars, respectively, the method of the present invention can be used to plate domed (convex) copper pillars as well. Preferably, the copper pillars of the present invention are copper pillars with flat tops or dished tops. Most preferably, the copper pillars are dished (concave).

The copper electroplating bath used to plate the copper pillars of the present invention comprises one or more sources of copper ions, one or more acids, one or more sources of chloride, one or more levelers, one or more accelerators, one or more suppressors and one or more additional components conventionally included in copper electroplating baths and water as a solvent. Such copper electroplating baths have acid pH ranges. Preferably, the pH of the copper electroplating baths are 2 or less, more preferably, 1 or less, most preferably, less than 1. The same copper electroplating bath can be used to plate the entire copper pillar or, in the alternative, the copper electroplating bath used to plate the second section of the copper pillar or remainder of the copper pillar can be a copper electroplating bath which includes the minimal number of components to plate copper pillars. Such a copper electroplating bath consists of water, one or more sources of copper ions, one or more acids to provide an electrolyte and maintain an acid pH, preferably, 2 or less, more preferably 1 or less, most preferably less than 1, and, optionally, one or more sources of chloride, one or more levelers, one or more accelerators and one or more suppressors. Preferably, the second or alternative copper electroplating bath consists of water, one or more sources of copper ions, and one or more acids to provide an electrolyte and maintain an acid pH, preferably, 2 or less, more preferably 1 or less, most preferably less than 1. Examples of commercially available copper plating baths are INTERVIA™ 8540, 9000 and 9600 copper electroplating baths available from Dow Electronic Materials, Marlborough, Mass.

Tin or tin alloy solder bumps are then deposited on the tops of each copper pillar. The tin or tin alloy solder can be deposited on the tops of the copper pillars by conventional methods, such as electroplating, or chemical and physical vapor deposition. Preferably, the tin to tin alloy solder is deposited by electroplating solder bumps on the tops of the copper pillars. The entire structure of substrate 202 and 302 with the copper pillars 200 and 300, and photoresist 204 and 304 is then transferred to a plating bath containing solder, such as a tin solder, or tin alloy solder, such as a tin-silver or tin-lead alloy. Solder bumps 205 and 305 are electroplated on the substantially flat or dished surface of each copper pillar to fill portions of the vias. After plating the solder bumps, the photoresist is stripped from the substrate using solvent stripper or by other conventional means known in the art leaving an array of copper pillars with solder bumps on the substrate. The remainder of the seed layer not covered by pillars is removed through etching processes well known in the art. The copper pillars with solder bumps and substrate are then reflowed in a conventional reflow oven. An example of a reflow oven is FALCON 8500 tool from Sikiama International, Inc. which includes 5 heating and 2 cooling zones. Reflow cycles may range from 1-5. The reflow process results in the formation of a copper-tin intermetallic interface 208 and 308, wherein the % V is 20% or less, preferably, from 15% or less, more preferably, from 0.5% to 15%, most preferably, from 0% to 5%.

Alternatively, the copper pillars with the solder bumps are placed in contact with metal contacts of a substrate such as a printed circuit board (not shown), another wafer or die or an interposer (not shown) which may be made of organic laminates, silicon or glass. The solder bumps are heated by conventional processes known in the art to reflow the solder and join the copper pillars to the metal contacts (not shown) of the substrate. Conventional reflow processes for reflowing solder bumps may be used, such as the FALCON 8500 tool reflow oven from Sikiama International, Inc, described above. The copper pillars are both physically and electrically contacted to the metal contacts of the substrate. An underfill material can then be injected to fill space between the die, the pillars and the substrate. Conventional underfills which are well known in the art can be used.

To provide a metal contact and adhesion between the copper pillars and the semiconductor die during electroplating of the pillars, an underbump metallization layer typically composed of a material such as titanium, titanium-tungsten or chromium is deposited on the die. Alternatively, a metal seed layer, such as a copper seed layer, may be deposited on the semiconductor die to provide metal contact between the copper pillars and the semiconductor die. After the photosensitive layer has been removed from the die, all portions of the underbump metallization layer or seed layer are removed except for the portions underneath the pillars. Conventional processes known in the art may be used.

The aqueous copper electroplating baths of the present invention include one or more sources of copper ions, one or more acids, one or more accelerators (brighteners), one or more suppressors, one or more levelers, and, optionally, one or more sources of halide ions, preferably chloride, and water. Additional optional components such as buffers and antimicrobials can be included. Such additional optional components are conventional and well known to those of skill in the art. Many of such components are readily commercially available. Alternatively, the aqueous copper electroplating bath consists of one or more sources of copper ions, one or more acids, water, and, optionally, one or more accelerators, one or more suppressors, one or more levelers, one or more sources of halide ions, one or more buffers and one or more antimicrobials. Preferably, the alternative aqueous copper electroplating bath consists of one or more sources of copper ions, one or more acids and water. It is substantially free of any additional components. The alternative or second aqueous copper electroplating bath is used to plate the second section of the copper pillar as described above.

Sources of copper ions include, but are not limited to, copper sulfate; copper halides such as copper chloride; copper acetate; copper nitrate; copper tetrafluoroborate; copper alkylsulfonates; copper aryl sulfonates; copper sulfamate; copper perchlorate and copper gluconate. Exemplary copper alkane sulfonates include copper (C₁-C₆)alkane sulfonate and more preferably copper (C₁-C₃)alkane sulfonate. Preferred copper alkane sulfonates are copper methanesulfonate, copper ethanesulfonate and copper propanesulfonate. Exemplary copper arylsulfonates include, without limitation, copper benzenesulfonate and copper p-toluenesulfonate. Mixtures of copper ion sources may be used. One or more salts of metal ions other than copper ions may be added to the present electroplating baths. Preferably, the copper salts are present in an amount sufficient to provide copper ions at concentrations of 30 g/L to 70 g/L of plating solution. More preferably the amount of copper ions is from 40 to 60 g/L.

One or more acids are included in the aqueous copper electroplating baths to provide an acid copper plating bath. Preferably, the pH of the copper electroplating baths are 2 or less, more preferably, 1 or less, most preferably, less than 1. Acids include, but are not limited to, sulfuric acid, acetic acid, fluoroboric acid, alkanesulfonic acids such as methanesulfonic acid, ethanesulfonic acid, propanesulfonic acid and trifluoromethane sulfonic acid, aryl sulfonic acids such as benzenesulfonic acid, p-toluenesulfonic acid, sulfamic acid, hydrochloric acid, hydrobromic acid, perchloric acid, nitric acid, chromic acid and phosphoric acid. Preferred acids include sulfuric acid, methanesulfonic acid, ethanesulfonic acid, propanesulfonic acid, hydrochloric acid and mixtures thereof. The acids can be present at concentrations of 1 g/L to 400 g/L. Such acids are generally commercially available from a variety of sources.

Optionally, one or more sources of halide ions can be included in the aqueous copper electroplating baths of the present invention. One or more sources of chloride ions and bromide ions can be included in the copper electroplating baths. Chloride ion sources include, but are not limited to, copper chloride, sodium chloride, potassium chloride and hydrochloric acid. Sources of bromide ions include, but are not limited to, sodium bromide, potassium bromide and hydrogen bromide. Preferably, the halide ion is chloride. Halide ion concentrations can range from 0 to 200 ppm based on the plating bath, preferably, 50 ppm to 150 ppm, more preferably from 60 ppm to 100 ppm. Halide ion sources are generally commercially available.

Accelerators include, but are not limited to, N,N-dimethyl-dithiocarbamic acid-(3-sulfopropyl)ester; 3-mercapto-propylsulfonic acid-(3-sulfopropyl)ester; 3-mercapto-propylsulfonic acid sodium salt; carbonic acid,dithio-O-ethylester-S-ester with 3-mercapto-1-propane sulfonic acid potassium salt; bis-sulfopropyl disulfide; bis-(sodium sulfopropyl)-disulfide; 3-(benzothiazolyl-S-thio)propyl sulfonic acid sodium salt; pyridinium propyl sulfobetaine; 1-sodium-3-mercaptopropane-1-sulfonate; N,N-dimethyl-dithiocarbamic acid-(3-sulfoethyl)ester; 3-mercapto-ethyl propylsulfonic acid-(3-sulfoethyl)ester; 3-mercapto-ethylsulfonic acid sodium salt; carbonic acid-dithio-O-ethylester-S-ester with 3-mercapto-1-ethane sulfonic acid potassium salt; bis-sulfoethyl disulfide; 3-(benzothiazolyl-S-thio)ethyl sulfonic acid sodium salt; pyridinium ethyl sulfobetaine; and 1-sodium-3-mercaptoethane-1-sulfonate. Accelerators can be included in the aqueous copper electroplating baths in amounts of 0.1 ppm to 1000 ppm, preferably from 0.5 ppm to 500 ppm, more preferably from 0.5 ppm to 100 ppm.

Suppressors include, but are not limited to, polypropylene glycol copolymers and polyethylene glycol copolymers, including ethylene oxide-propylene oxide (“EO/PO”) copolymers and butyl alcohol-ethylene oxide-propylene oxide copolymers. The weight average molecular weight of the suppressors can range from 800-15000, preferably from 1000 to 15,000. When such suppressors are used, they are preferably present at concentrations of 0.5 g/L to 15 g/L based on the weight of the composition, more preferably from 0.5 g/L to 5 g/L.

While a variety of levelers can included in the aqueous copper electroplating baths of the present invention, preferably, the levelers are reaction products of one or more amine compounds and one or more polyepoxide as disclosed in U.S. 2007/0007143, the entire disclosure of which is hereby incorporated in its entirety by reference. Preferably, the amine compound is a heterocyclic nitrogen compound, more preferably, the heterocyclic nitrogen compound is an imidazole and preferably, the polyepoxides are chosen from 1,4-butanediol diglycidyl ether, ethylene glycol diglycidyl ether, di(ethylene glycol) diglycidyl ether, glycerol diglycidyl ether, neopentyl glycol diglycidyl ether, 1,3-butandiol diglycidyl ether, propylene glycol diglycidyl ether, di(propylene glycol) diglycidyl ether, poly(ethylene glycol) diglycidyl ether compounds and poly(propylene glycol) diglycidyl ether compounds. Most preferably, the polyepoxide is chosen from glycerol diglycidyl ether and neopentyl glycol diglycidyl ether.

Preferably, the levelers can be prepared by dissolving a desired amount of one or more amines in water and heating the solution to about 40-90° C. with stirring. The one or more polyepoxide compounds are then added to the solution with continued stirring. Following addition of the polyepoxide compound, the reaction mixture is heated to about 75-95° C. for about 4-8 hours. After stirring for 12-18 hours, the reaction mixture is then diluted with water and the pH is adjusted to about 7.

The ratio of the one or more amine compounds to the one or more polyepoxide compounds used to prepare the levelers can be from 0.1:10 to 10:01. Preferably, the ratio is 0.5:5 to 5:0.5, more preferably, from 0.5:1 to 1:0.5.

Preferably, the levelers have a number average molecular weight (Mn) of 1000 to 10,000. Preferably, the levelers have weight average molecular weight (Mw) values of 1000 to 50,000, more preferably, from 1000 to 20,000, even more preferably from 1500 to 5000, or 5000 to 15,000.

The amount of the levelers used in the copper electroplating baths can range from 0.25 ppm to 1000 ppm, preferably, from 0.5 ppm to 500 ppm, more preferably, from 5 ppm to 500 ppm, based on the total weight of the plating bath.

The aqueous copper electroplating baths can also include other leveling agents. Such leveling agents include, but are not limited to, those disclosed in U.S. Pat. No. 6,610,192 to Step et al., U.S. Pat. No. 7,128,822 to Wang et al., and U.S. Pat. No. 6,800,188 to Hagiwara et al., and U.S. Patent Publication Nos. 2017/0042037, 2017/0037526, 2017/0037527 and 2017/0037528, the disclosures of which are incorporated herein in their entirety by reference.

The aqueous copper electroplating baths can be used at temperatures from 10 to 65° C. or higher. Preferably, the temperature of the plating composition is from 15 to 50° C. and more preferably from 20 to 40° C.

Preferably, the copper electroplating baths are agitated during use. Any suitable agitation method may be used and such methods are well-known in the art. Suitable agitation methods include, but are not limited to: air sparging, work piece agitation, and impingement.

Although tin or tin alloy solder can be deposited on the top of the copper pillars by conventional methods well known in the art, such as electroplating and chemical and physical vapor deposition methods, preferably, tin or tin alloy solder are electroplated on the tops of the copper pillars, more preferably tin-silver alloy is electroplated on the tops of the copper pillars. Conventional aqueous tin-silver electroplating baths and methods for electroplating tin-silver solder, well known to those of skill in the art, can be used. Examples of commercially available tin alloy electroplating baths are SOLDERON™ TS4000 and TS6000 tin-silver alloy electroplating baths available from Dow Electronic Materials, Marlborough, Mass.

A preferred aqueous tin-silver electroplating bath includes one or more sources of tin ions chosen from such as tin halides, tin sulfates, tin alkane sulfonates, tin alkanol sulfonates, and acids. One or more sources of silver ions chosen from silver halides, silver gluconate, silver citrate, silver lactate, silver nitrate, silver sulfates, silver alkane sulfonates and silver alkanol sulfonates. One or more tin salts are included in the tin-silver alloy baths in amounts of 30 g/L to 100 g/L, preferably from 50 g/L to 100 g/L. One or more silver salts are included in the tin-silver electroplating baths in amounts of 0.01 g/L to 20 g/L, preferably, from 0.01 g/L to 15 g/L.

One or more acids are included in the tin-silver alloy bath. Acids include, but are not limited to, arylsulfonic acids, alkanesulfonic acids, such as methanesulfonic acid, ethanesulfonic acid and propanesulfonic acid, aryl sulfonic acids such as phenylsulfonic acid and tolylsulfonic acid, and inorganic acids such as sulfuric acid, sulfamic acid, hydrochloric acid, hydrobromic acid and fluoroboric acid. Preferrably, the acids are chosen from alkane sulfonic acids and aryl sulfonic acids. One or more acids are included in amounts of 0.01 g/L to 500 g/L, preferably, from 10 g/L to 400 g/L, more preferably, from 50 g/L to 200 g/L.

One or more dihydroxy bis-sulfide compounds can be included in the tin-silver alloy bath. Such compounds are chosen from 2,4-dithia-1,5-pentanediol, 2,5-dithia-1,6-hexanediol, 2,6-dithia-1,7-heptanediol, 2,7-dithia-1,8-octanediol, 2,8-dithia-1,9-nonanediol, 2,9-dithia-1,10-decanediol, 2,11-dithia-1,12-dodecanediol, 5,8-dithia-1,12-dodecanediol, 2,15-dithia-1,16-hexadecanediol, 2,21-dithia-1,22-doeicasanediol, 3,5-dithia-1,7-heptanediol, 3,6-dithia-1,8-octanediol, 3,8-dithia-1,10-decanediol, 3,10-dithia-1,8-dodecanediol, 3,13-dithia-1,15-pentadecanediol, 3,18-dithia-1,20-eicosanediol, 4,6-dithia-1,9-nonanediol, 4,7-dithia-1,10-decanediol, 4,11-dithia-1,14-tetradecanediol, 4,15-dithia-1,18-octadecanediol, 4,19-dithia-1,22-dodeicosanediol, 5,7-dithia-1,11-undecanediol, 5,9-dithia-1,13-tridecanediol, 5,13-dithia-1,17-heptadecanediol, 5,17-dithia-1,21-uneicosanediol and 1,8-dimethyl-3,6-dithia-1,8-octanediol. Such compounds are included in amounts of 0.1 g/L to 15 g/L, preferably, from 0.5 g/L to 10 g/L.

One or more mercaptotetrazoles can be included in the tin-silver alloy bath. Such mercaptotetrazoles are chosen from 1-(2-diethylaminoethyl)-5-mercapto-1,2,3,4-tetrazole, 1-(3-ureidophenyl)-5-mercaptotetrazole, 1-((3-N-ethyl oxalamido)phenyl)-5-mercaptotetrazole, 1-(4-acetamidophenyl)-5-mercapto-tetrazole and 1-(4-carboxyphenyl)-5-mercaptotetrazole. The mercaptotetrazole compounds can be included in the bath in amounts of 1 g/L to 200 g/L, preferably, 5 g/L to 150 g/L.

Optionally, one or more suppressors can be included in the tin-silver alloy baths. Such suppressors include, but are not limited to, alkanol amines, polyethyleneimines and alkoxylated aromatic alcohols. Suitable alkanol amines include, but are not limited to, substituted or unsubstituted methoxylated, ethoxylated, and propoxylated amines, for example, tetra (2-hydroxypropyl)ethylenediamine, 2-{[2-(dimethylamino)ethyl]-methylamino}ethanol, N,N′-bis(2-hydroxyethyl)-ethylenediamine, 2-(2-aminoethylamine)-ethanol, and combinations thereof. Preferably, they are included in amounts of 0.5 g/L to 15 g/L, more preferably, from 1 g/L to 10 g/L.

Polyethyleneimines include, but are not limited to, substituted or unsubstituted linear or branched chain polyethyleneimines or mixtures thereof having a molecular weight of from 800-750,000. Suitable substituents include, for example, carboxyalkyl, for example, carboxymethyl, carboxyethyl.

Alkoxylated aromatic alcohols include, but are not limited to ethoxylated bis phenol, ethoxylated beta naphthol, and ethoxylated nonyl phenol.

Optionally, one or more reducing agents can be added to the baths to assist in keeping the tin in a soluble, divalent state. Reducing agents include, but are not limited to hydroquinone, hydroquinone sulfonic acid, potassium salt and hydroxylated aromatic compounds, such as resorcinol and catechol. Such reducing agents are included in amounts of 0.01 to 20 g/L, preferably, from 0.1 to 5 g/L.

Optionally, one or more grain refiners can be included in the tin-silver alloy baths. Such gain refiners include, but are not limited to, alkoxylates, such as the polyethoxylated amines JEFFAMINE T-403 or TRITON RW, or sulfated alkyl ethoxylates, such as TRITON QS-15, and gelatin or gelatin derivatives. Alkoxylated amine oxides also may be included. While a variety of alkoxylated amine-oxide surfactants are known, preferably, low-foaming amine oxides are used. Such preferred alkoxylated amine oxide surfactants have viscosities of less than 5000 cps measured using a Brookfield LVT Viscometer with a #2 spindle. Preferably, this viscosity is determined at ambient temperatures. Preferably, such grain refiners are included in amounts of 0.5 g/l to 20 g/L.

The tin-silver alloy baths are acidic. Preferably, the tin-silver alloy baths have a pH of less than 1 to 2, more preferably, less than 1.

Tin-silver alloy is electroplated from 0.05 ASD to 25 ASD, preferably, from 0.05 ASD to 10 ASD.

The tin-silver alloys can be electroplated from room temperature to 55° C., preferably from room temperature to 40° C., more preferably, from room temperature to 30° C.

The following examples are intended to further illustrate the invention, but are not intended to limit its scope.

### Examples 1-5 (Invention)

### Copper Pillars with Reduced Voiding

An aqueous acid copper electroplating bath is prepared having the components disclosed in Table 1 below.

TABLE 1

| Component | Amount | |
|---|---|---|
| Copper (II) ions from Copper sulfate | 55 | g/L |
| pentahydrate | | |
| Sulfuric acid (98 wt %) | 70 | g/L |
| bis-(sodium sulfopropyl)-disulfide | 12 | mg/L |
| Chloride from hydrochloric acid | 90 | mg/L |
| EO/PO copolymer having a weight average | 0.5 | g/L |
| molecular weight of 1,000 and terminal | | |
| hydroxyl groups | | |
| Copolymer of imidazole and 1,4-butanediol | 100 | mg/L |
| diglycidyl ether (molar ratio of about 1:1) | | |

| | |
|---|---|
| Water | To one liter |

The pH of the bath is less than 1.

An aqueous acid tin-silver alloy electroplating bath for solder bumps is prepared having the components disclosed in Table 2 below.

TABLE 2

| Component | Amount | |
|---|---|---|
| Tin (II) ions from tin methane sulfonate | 75 | g/L |
| Methane sulfonic acid (70 wt %) | 75 | g/L |
| Silver (I) ions from silver methane sulfonate | 1.2 | g/L |
| EO/PO copolymer having a weight average | 50 | g/L |
| molecular weight of greater than 1000 with | | |
| terminal hydroxyl groups | | |
| 1-(2-diethylamino-ethyl)-5-mercapto-1,2,3,4- | 80 | g/L |
| tetrazole | | |
| 2,7-dithia-1,8-octanediol | 5 | g/L |
| hydroquinone | 1.2 | g/L |

| | |
|---|---|
| Water | To one liter |

The pH of the bath was less than 1.

### Example 1

A 300 mm silicon wafer segment with a patterned photoresist 50 μm thick and a plurality of apertures (available from IMAT, Inc., Vancouver, Wash.) are immersed in the copper electroplating bath. The anode is a soluble copper electrode. The wafer and the anode are connected to a rectifier and a plurality of copper pillars are electroplated on the exposed metal seed layer at the bottom of the apertures which are circular to enable the formation of pillars having a columnar morphology. The aperture diameters are 50 μm to enable the formation of pillars with an average diameter of 45 μm. The temperature of the copper electroplating bath is at 25° C. throughout plating. The initial average current density during plating of the first 33 μm (first vertical section) of the copper pillars is 20 ASD followed by decreasing the average current density to 0.5 ASD for the last 2 μm (second vertical section) of the copper pillars. The overall average current density for electroplating the copper pillars to their final height of 35 μm is 14.9 ASD.

The heights and TIR of the pillars are measured using an optical white light LEICA DCM 3D microscope. The % TIR is determined by the following equations:

% TIR=[height_{center}−height_{edge}]/heightₘₐₓ×100,

TIR=height_{center}−height_{edge}

The % TIR for the pillars is determined to be about −7.9%. The pillars have a dished or concave top morphology.

The wafer segment with the photoresist and the copper pillars are then immersed in the tin-silver electroplating bath disclosed in Table 2. The anode is a soluble tin electrode. The wafer and the anode are connected to a rectifier and tin-silver solder bumps 25 μm tall are plated on the top of each copper pillar. The tin-silver bath is at 25° C. during plating and the average current density is 10 ASD.

After the tin-silver solder is plated on the copper pillars, the photoresist is then stripped with BPR photostripper solution available from the Dow Chemical Company leaving an array of copper pillars on the wafer with tin-silver solder bumps on the top of each pillar.

The wafer segment with the copper pillars and tin-silver solder bumps are then placed in a FALCON 8500 tool reflow oven from Sikiama International, Inc. The wafer segment is passed through 5 reflow zones (140° C., 190° C., 190° C., 230° C. and 260° C.), 30 sec per zone (20 sec in transit and 10 sec stationary); cool down zone, and ramp rate 40 C/sec.

The wafer segment is removed from the reflow oven and the % V is determined along the interface of where the copper-tin intermetallic and the copper of the pillar meet. The average length of the copper-tin intermetallic for the plurality of copper pillars is 46.5 μm and the width or thickness of the copper-tin intermetallic where the voids are counted from the copper to within the copper-tin intermetallic is 1 μm. The counting of the length of each void along the length and width of the interface and summing the lengths is done by ImageJ software available from NIH (see https://imagej.nih.gov/ij/).

The process steps for counting the number and the length of each void using the ImageJ program is as follows:
1. A cross-section (at the center axis) SEM image of each copper pillar with solder bump is received;
2. Open image in ImageJ program;
3. Draw line on scale bar in the image (yellow line);
4. Go to “analyze”—“Set scale”—and enter “known distance” based on the scale and press “OK”;
5. Right click on the “fixed length line tool” and set the “desired line length” to be 45 length of the copper-tin intermetallic along the top of the copper pillar);
6. Select the “centered” option and hit “OK”;
7. Place the cursor at the center of the pillar just below the Cu—Cu₃Sn IMC line;
8. Select the “rectangle” tool and draw a rectangle that captures the Cu—Cu₃Sn IMC along the 45 μm line;
9. Go to “Image” and “crop”; and
10. At this point, zoom in at the void(s) and draw a line along the length or diameter of the void to measure the void(s) length or diameter.
   The equation used for determining the % V for a pillar or plurality of pillars is as follows: Sum of the total length of the number of voids counted along the length (μm) of the copper-tin intermetallic interface and within a width or thickness of the copper-tin intermetallic interface

of 1 μm/pillar diameter(μm)×100

The % V of the plurality of pillars is determined to be about 12%. None of the copper pillars show any observable signs of cracking or failure at the copper-tin intermetallic interface.

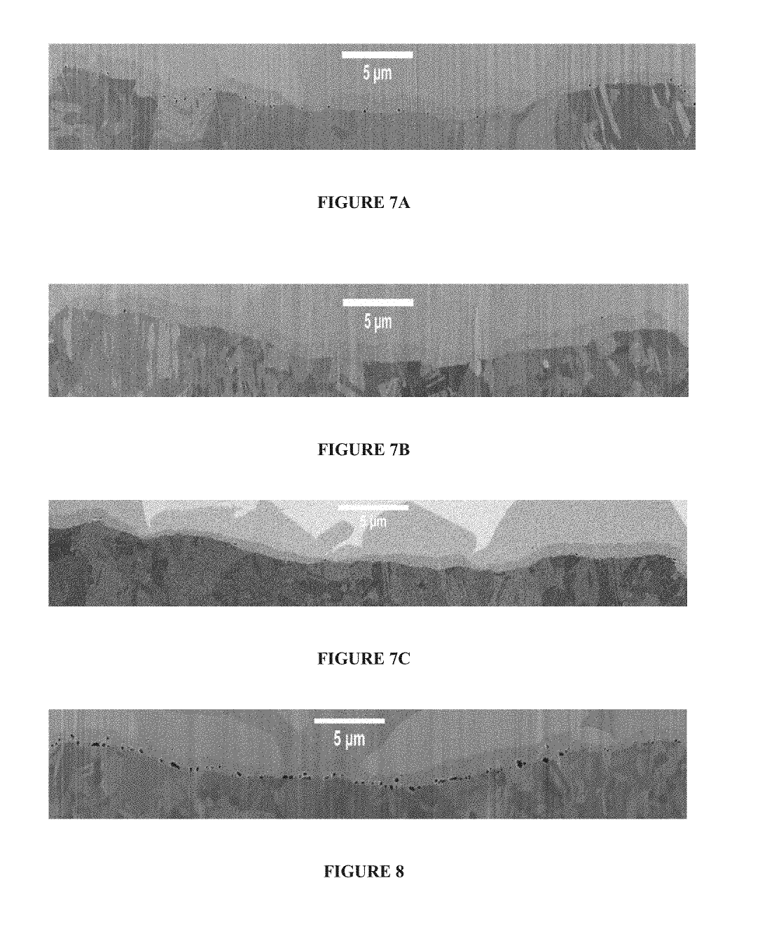

FIG. 7A is a 5000×SEM of a cross section at the center of one of the copper pillars with the tin-silver solder bump post reflow. The bottom dished portion of the SEM is the top of the copper pillar. The lighter upper part of the SEM is the copper-tin intermetallic. The dark spots at the interface or bond line of the copper of the pillar and the copper-tin intermetallic are voids of relatively very small length.

### Example 2

The method disclosed in Example 1 above is repeated except that the current density applied during the plating of the last 2 μm (second vertical section) of the copper pillars is 4 ASD. The average plating rate for the copper pillars is 16.3 ASD. The tops of the copper pillars are then plated with tin-silver solder bumps from the tin-silver bath disclosed in Table 2. The copper pillars have a % TIR of about −7.5% as measured using an optical white light LEICA DCM 3D microscope. The morphology of the top is dished or concave. The photoresist is stripped and the array of copper pillars with tin-silver bumps are reflowed according to the process described above.

The void lengths for these copper pillars is determined by using the ImageJ program as described above. The % V is only about 1%. None of the copper pillars show any observable signs of cracking or failure at the copper-tin intermetallic interface.

FIG. 7B is a 5000×SEM of a cross section at the center of one of the copper pillars post reflow. As in FIG. 7A, the bottom dished portion is the top of the copper pillar. The lighter upper part of the SEM is the copper-tin intermetallic. Although the copper pillars include voids, as determined by ImageJ program, the lengths of the voids are very small such that no voids are observable in FIG. 7B.

### Example 3

The method disclosed in Example 1 above is repeated except that the current density applied during the plating of the last 2 μm (second vertical section) of the copper pillars is 6 ASD. The average plating rate for the copper pillars is 17.6 ASD. The tops of the copper pillars are then plated with tin-silver solder bumps from the tin-silver bath disclosed in Table 2. The copper pillars have a % TIR of about −8%. The top of the pillars have a dished morphology. The photoresist is stripped and the array of copper pillars with tin-silver bumps are reflowed according to the process described in Example 1 above.

The void lengths for these copper pillars is determined by using the ImageJ software program. The % V is 5%. None of the copper pillars show any observable signs of cracking or failure at the copper-tin intermetallic interface.

FIG. 7C is a 5000×SEM of a cross section at the center of one of the copper pillars post reflow. As in FIG. 7A, the bottom dished portion is the top of the copper pillar. The lighter upper part of the SEM is the copper-tin intermetallic. Some voids are visible very near the surface of the copper.

### Example 4

The method disclosed in Example 1 above is repeated except that the current density applied during the plating of the last 2 μm (second vertical section) of the copper pillars is 8 ASD. The average plating rate for the copper pillars is 18.4 ASD. The tops of the copper pillars are then plated with tin-silver solder bumps from the tin-silver bath disclosed in Table 2. The copper pillars have a % TIR of about −8.2%. The top morphology is dished. The photoresist is stripped and the array of copper pillars with tin-silver bumps are reflowed according to the process described in Example 1 above.

The void lengths for these copper pillars are determined by using the ImageJ software program. The % V is 5% as in Example 3. None of the copper pillars show any observable signs of cracking or failure at the copper-tin intermetallic interface.

### Example 5

The method disclosed in Example 1 above is repeated except that the current density applied during the plating of the last 2 μm (second vertical section) of the copper pillars is 10 ASD. The average plating rate for the copper pillars is 18.9 ASD. The tops of the copper pillars are then plated with tin-silver solder bumps from the tin-silver bath disclosed in Table 2. The copper pillars have a % TIR or about −8.3%. The tops of the copper pillars have a dished morphology. The photoresist is stripped and the array of copper pillars with tin-silver bumps are reflowed according to the process described in Example 1 above.

The void lengths numbers for these copper pillars was determined by using the ImageJ program. The % V was 14%. None of the copper pillars show any observable signs of cracking or failure at the copper-tin intermetallic interface.

The table below summarizes the plating parameters and results of Examples 1-5

TABLE 3

| Parameter | Example 1 | Example 2 | Example 3 | Example 4 | Example 5 |
|---|---|---|---|---|---|
| 33 μm | 20 | 20 | 20 | 20 | 20 |
| Plating ASD | | | | | |
| 2 μm Plating | 0.5 | 4 | 6 | 8 | 10 |
| ASD | | | | | |
| Avg. Pillar | 14.9 | 16.3 | 17.6 | 18.4 | 18.9 |
| Plating ASD | | | | | |
| % V | 12% | 1% | 5% | 5% | 14% |

### Example 6 (Comparative)

### Copper Pillars with High Voiding at the Copper-Tin Interface

A 300 mm silicon wafer segment with a patterned photoresist 50 μm thick and a plurality of apertures (available from IMAT, Inc., Vancouver, Wash.) is immersed in the copper electroplating bath of Table 1 in Examples 1-5. The anode is a soluble copper electrode. The wafer and the anode are connected to a rectifier and copper pillars are electroplated on the exposed metal seed layer at the bottom of the apertures which are circular to enable the formation of pillars having a columnar morphology. The aperture diameters are 50 μm to enable the formation of pillars with an average diameter of 45 μm. The temperature of the copper electroplating bath is at 25° C. throughout plating. The average current density during plating of the 35 μm high copper pillars is 20 ASD without any decrease in the average current density as in Examples 1-5 above.

The wafer segment with the photoresist and the copper pillars is then immersed in the tin-silver electroplating bath disclosed in Table 2. The anode is a soluble tin electrode. The wafer and the anode were connected to a rectifier and tin-silver solder bumps 25 μm tall are plated on the top of each copper pillar. The tin-silver bath is at 25° C. during plating and the average current density is 10 ASD.

After the tin-silver solder is plated on the copper pillars, the photoresist is then stripped with BPR photostripper solution available from the Dow Chemical Company leaving an array of copper pillars on the wafer with tin-silver solder bumps on the top of each pillar. The % TIR of the pillars is −9.6%. The top of each pillar has a dished morphology.

The wafer segment with the copper pillars and tin-silver solder bumps is then placed in a FALCON 8500 tool reflow oven from Sikiama International, Inc. The wafer segment passed through 5 reflow zones (140° C., 190° C., 190° C., 230° C. and 260° C.), 30 sec per zone (20 sec in transit and 10 sec stationary); cool down zone, and ramp rate 40 C/sec.

The wafer segment is removed from the reflow oven and the % V is determined along the interface of where the copper-tin intermetallic and the copper of the pillar meet to a thickness of 1 μm. The counting of the length of each void along the interface and summing the lengths is done by ImageJ software. The % V is 40%. This is a significant increase in voids in comparison to the much lower % V of the invention in Examples 1-5. FIG. 8 is a 5000× SEM of a cross section at the center of one of one of the dished copper pillars post reflow. The SEM shows significant voiding and voids having varying lengths (diameters) along the bond line. A majority of the copper pillars showed cracks along the copper-tin interface with the tin-silver solder bumps.

What is claimed is:

1. A copper pillar comprising a horizontal base, a vertical section comprising a bottom side and a top side opposite to the bottom side, wherein the bottom side of the vertical section is joined to the horizontal base; a tin or tin alloy solder bump is joined to the top side of the vertical section by a copper-tin intermetallic interface, wherein along a length of the copper-tin intermetallic interface and from copper of the copper pillar to within the copper-tin intermetallic interface of 5 μm there is a % V=20% or less.

2. The copper pillar of claim 1, wherein the % V is from 0.5% to 15%.

3. The copper pillar of claim 1, wherein the top side of the copper pillar comprises a flat, domed or dished morphology.

4. A method of electroplating copper pillars comprising:
a) providing a substrate comprising a layer of photoresist, wherein the layer of photoresist comprises a plurality of apertures;
b) providing a first copper electroplating bath comprising one or more sources of copper ions, one or more acids, one or more sources of chloride, one or more levelers, one or more accelerators; and one or more suppressors;
c) immersing the substrate comprising the layer of photoresist with the plurality of apertures in the first copper electroplating bath;
d) electroplating a first section of a copper pillar in each of the plurality of apertures at a first current density followed by electroplating a second section of the copper pillar in each of the plurality of apertures at a lower current density than the first current density with the first copper electroplating bath or, in the alternative, electroplating the second section of the copper pillar in each of the plurality of apertures at the lower current density with a second copper electroplating bath consisting of water, one or more sources of copper ions, one or more acids, and, optionally, one or more sources of chloride, one or more levelers, one or more accelerators and one more suppressors;
e) depositing a tin or tin alloy solder bump on a top of the second section of each copper pillar;
f) stripping the photoresist from the substrate leaving an array of copper pillars with tin or tin alloy solder bumps on the top of the second section of each copper pillar; and
g) reflow the array.

5. The method of claim 2, wherein the first current density is greater than 10 ASD.

6. The method of claim 2, wherein the second current density is 10 ASD or less.
